(19) United States
(12) Patent Application Publication
(10) Pub. No.: US 2010/0059119 A1
(43) Pub. Date: Mar. 11, 2010

(54) SOLAR CELL AND METHOD OF MANUFACTURING THE SAME

(75) Inventors: Sun Jin YUN, Daejeon-City (KR); JungWook LIM, Daejeon-City (KR); Sang Hoon KIM, Seoul (KR); Hyun Tak KIM, Daejeon-City (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon City (KR)

(21) Appl. No.: 12/554,099

(22) Filed: Sep. 4, 2009

(30) Foreign Application Priority Data
Sep. 9, 2008 (KR) 10-2008-0088893
Dec. 18, 2008 (KR) 10-2008-0129395

(51) Int. Cl. H01L 31/00; H01L 21/20

(52) U.S. Cl. 136/261; 438/73; 257/E21.09

(57) ABSTRACT

Provided are a solar cell and a method of manufacturing the same. The solar cell includes a substrate; and a light-absorbing layer formed below the substrate and comprising a plurality of semiconductor layers which comprise Si or SiGe and have different Ge composition ratios. According to the present invention, stress and crystal defects that may occur by sudden changes of the composition of Ge can be minimized, and a more efficient solar cell can be fabricated.

### CROSS-REFERENCE TO RELATED PATENT APPLICATION

This application claims the benefit of Korean Patent Application Nos. 10-2008-0088893, filed on Sep. 9, 2008 and 10-2008-0129395, filed on Dec. 18, 2008, in the Korean Intellectual Property Office, the disclosure of which is incorporated herein in its entirety by reference.

### BACKGROUND OF THE INVENTION

1. Field of the Invention

The present invention relates to a solar cell and a method of manufacturing the same, and more particularly, to a solar cell which can minimize stress and crystal defects by forming a light-absorbing layer so that a Ge composition ratio of a silicon-germanium (SiGe) thin film solar cell gradually varies.

2. Description of the Related Art

Recently, fossil fuels on the earth are being depleted and the global environment pollution is getting severe due to the use of the fossil fuels.

Thus, different ways of obtaining energy not inducing pollution must be solved on the earth as soon as possible. Also, the need for clean, renewable energy that can be replaced with fossil fuels has increased, and the best renewable energy is solar light since solar light is available as long as the sun and the earth exist and does not generate air pollution.

A solar cell converting solar energy into electricity by the use of solar light is classified as a solar heat cell and a solar light cell. The solar heat cell generates steam necessary to rotate a turbine by using concentrated solar heat (temperature 1000° C.). The solar light cell converts photons into electrical energy by using the characteristics of a semiconductor. In general, a solar cell denotes a solar light cell and thus hereinafter, referred to as a solar cell.

Solar cells obtain power from a photovoltaic effect. That is, a p-type semiconductor generating electrical conduction by holes and an n-type semiconductor generating electrical conduction by electrons are joined. Then, electrons, holes, and charges are created by light, and thus, current flows to generate a photovoltaic effect.

However, the energy production cost of solar cells is much higher than that of thermal power generation, waterpower generation, or nuclear power generation. Therefore, there are needs for a low production cost, easy installation, and highly efficient production in relation to an occupying area of the solar cells.

At present, a solar cell, which has been produced and sold the most, is a bulk-type silicon (Si) solar cell, which occupies 90% of the solar cell market. However, in the case of the bulk-type Si solar cell, as an undersupply of Si is anticipated and lower-priced solar cells are required, the development of a thin film solar cell is being accelerated.

The thin film solar cell market occupies 11.6% of the entire solar cell market in 2007. Thin film solar cells include Si thin film solar cells formed by applying a Si thin film on a substrate such as a glass substrate, a metal substrate, or the like, CuInGaSe (CIGS)-based thin film solar cells, CdTe-based thin film solar cells, dye sensitized solar cell (DSSC) solar cells, and organic thin film solar cells, etc. It is anticipated that amorphous Si thin film solar cells will occupy about 57.5%, CdTe-based thin film solar cells will occupy about 24.4%, CIS/CIGS-based thin film solar cells will occupy about 18.1% of the inorganic thin film solar cell market about in 2010.

A small quantity of Si is used for the thin film solar cell as compared to the bulk-type Si solar cell manufactured on a Si substrate, thus the material cost of the thin film solar cell is low. The amount of Si used in the amorphous Si solar cells is about one hundredth of the amount of Si used in the bulk-type Si solar cell, and thus the manufacturing cost of the thin film solar cell can be lower even when a larger substrate is used for producing the same power due to lower efficiency of thin film solar cell than bulk-Si solar cell.

FIG. 1 is a table showing the manufacturing cost and light conversion efficiency according to a type of a silicon solar cell, wherein the data was obtained from the Korea Institute of Energy Research in August 2007.

Referring to FIG. 1, the light conversion efficiency of a thin film solar cell is about 8%, which is extremely lower than that of a bulk-type Si solar cell (single crystal is 17%, polycrystal is 14%).

A method of decreasing the manufacturing cost and installation cost of a Si thin film solar cell further is closely connected with a method of increasing light conversion efficiency of a solar cell. In particular, in the case of South Korea, for example, a country having a narrow land area, the area of a solar cell is the cost itself.

A method of increasing efficiency of the Si thin film solar cell includes a method of increasing characteristics such as crystallinity of a semiconductor layer, which is a light-absorbing layer, a method of increasing light absorption efficiency by adding a second material to a Si light-absorbing layer, a method of decreasing defects at interfaces consuming carriers such as electrons, holes, etc., and the like.

Solar light includes ultraviolet (UV) rays, infrared rays as well as visible rays, which have the highest intensity. Semiconductors used in a light-absorbing layer of solar light have bandgaps of more than 1 eV (wavelength <1240 nm). A single crystal Si thin film, a GaAs thin film, and a CdTe thin film have bandgaps of 1.12 eV, 1.43 eV, and 1.49 eV, respectively. Since such thin films cannot effectively absorb light with an infrared region that is less than 1 eV, materials having a lower bandgap than 1 eV have attracted attention. One of these materials is Ge, which, in the case of a single crystal, the bandgap is 0.67 eV. Thus, a SiGe solar cell is attracting attention over a Si solar cell. When the Si or Ge films are fabricated to be amorphous films, their bandgaps increase to 1.4˜1.9 eV for Si or 1.0˜1.4 eV for Ge.

As an attempt in increasing efficiency of a SiGe thin film solar cell by changing its structure, a technology of introducing a quantum well structure in a space charge area of a Si p-n junction diode as an active base area having a high absorbance has been proposed.

### SUMMARY OF THE INVENTION

The present invention provides a solar cell which can minimize stress and crystal defects by forming a light-absorbing layer so that a Ge composition ratio of a silicon-germanium (SiGe) thin film solar cell gradually varies.

According to an aspect of the present invention, there is provided a solar cell including: a substrate; and a light absorbing layer formed below the substrate deposited by electrode layer and comprising a plurality of semiconductor layers which include Si or SiGe and have different Ge composition ratios.

According to another aspect of the present invention, there is provided a method of manufacturing a solar cell, including: loading a substrate; depositing a semiconductor layer including Si or SiGe on the substrate deposited by electrode layer; and forming a light-absorbing layer by depositing at least one semiconductor layer having a Ge composition ratio different from that of the previously deposited semiconductor layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a table showing the manufacturing cost and light conversion efficiency according to a type of silicon solar cell.

FIG. 2A shows a conventional silicon (Si) thin film solar cell, and FIG. 2B shows a silicon-germanium (SiGe) thin film solar cell according to an embodiment of the present invention.

FIG. 3A shows a SiGe thin film solar cell according to an embodiment of the present invention, and FIG. 3B shows a light-absorbing layer of the SiGe thin film solar cell of FIG. 3A in more detail.

FIG. 4 shows a bandgap of the SiGe thin film solar cell of FIG. 3A.

FIG. 5 shows a solar cell using an opaque substrate, according to another embodiment of the present invention.

FIG. 6A shows a conventional SiGe thin film solar cell having a triple junction structure, and FIG. 6B shows a SiGe thin film solar cell having a triple junction structure, according to an embodiment of the present invention.

FIG. 7 is a flowchart of a method of manufacturing a SiGe thin film solar cell, according to an embodiment of the present invention.

### DETAILED DESCRIPTION OF THE INVENTION

The present invention will now be described more fully with reference to the accompanying drawings, in which exemplary embodiments of the invention are shown. In the description, the detailed descriptions of well-known functions and structures may be omitted so as not to hinder the understanding of the present invention.

When one element “includes” one component in the present invention, it means that the element further includes another element instead of excluding another element as long as A description to the contrary does not exist.

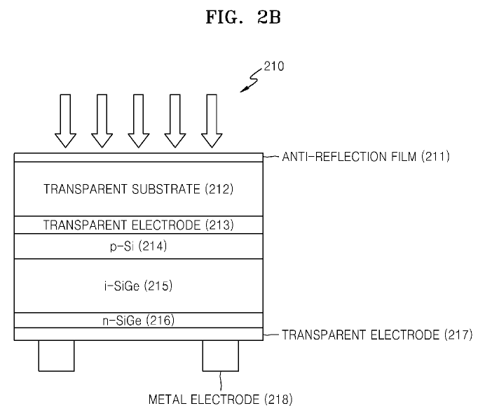

FIG. 2A shows a conventional silicon (Si) thin film solar cell 200, and FIG. 2B shows a silicon-germanium (SiGe) thin film solar cell 210 according to an embodiment of the present invention.

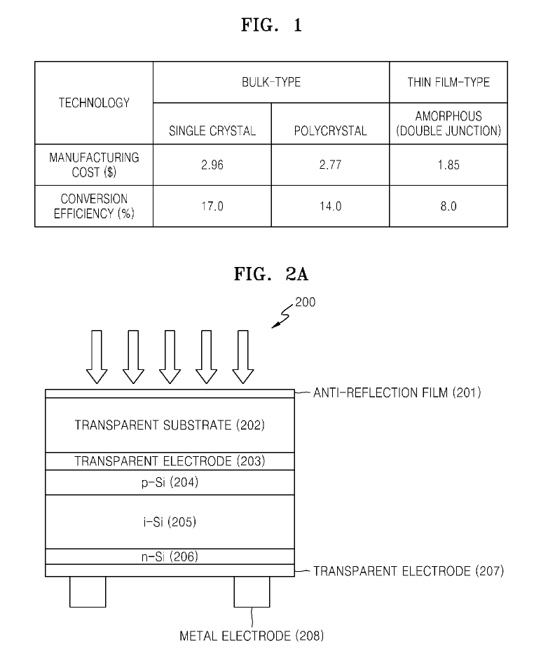

Referring to FIG. 2A, the Si thin film solar cell 200 includes an anti-reflection film 201, a transparent substrate 202, transparent electrodes 203 and 207, a p-type Si semiconductor layer 204, an i-type Si semiconductor layer 205, an n-type Si semiconductor layer 206, and metal electrodes 208. A metal electrode layer can be used instead of transparent electrode 207 and metal electrode 208. Referring to FIG. 2B, the structure of the SiGe thin film solar cell 210 according to the present embodiment of the present invention is similar to that of the Si thin film solar cell 200 of FIG. 1, but light-absorbing layers 214, 215, and 216 which are respectively formed as a p-type semiconductor layer, an i-type semiconductor layer, and an n-type semiconductor layer may include Ge as well as Si. In FIG. 2B, a metal electrode layer can be used instead of transparent electrode 207 and metal electrode 208.

In the Si thin film solar cell 200, unlike a bulk-type Si solar cell, a light-absorbing layer has a multi-layered structure including the p-type Si semiconductor layer 204, the intrinsic Si (i-Si) semiconductor layer 205, and the n-type Si semiconductor layer 206, similar to the SiGe thin film solar cell 210 of FIG. 2B.

The transparent substrate 202 may be a glass substrate or a flexible substrate, such as a polymer film or the like. The transparent substrate 202 may be replaced with opaque substrates such as flexible stainless steel film, a metal film, or ceramic substrate according to its use. When the transparent substrate 202 is an opaque substrate, the Si thin film solar cell 200 may have a reverse structure to the structure using the transparent substrate 202. In a reverse structure, the transparent electrode 203 is replaced with metal electrode or conducting multilayer containing a transparent conducting layer and a metal layer.

Unlike the current embodiment, an anti-reflection film may be interposed between the transparent substrate 202 and the transparent electrode 203, or a buffer layer may be interposed therebetween in order to improve a characteristic of each interface.

In the SiGe thin film solar cell 210, a composition of Ge varies according to the manufacturing conditions of SiGe, and a research providing experiment conditions for obtaining the highest efficiency has been conducted. In the case of prior research, when the amount of Ge exceeds 20%, it was found that the efficiency of the SiGe thin film solar cell 210 decreased. That is, as the amount of Ge increases, many defects around interfaces between a SiGe layer and a Si layer occur due to lattice mismatch between the Si and SiGe, and as crystallinity of the thin film solar cell 210 decreases, carriers generated by the defects and the interfaces are trapped, thereby significantly decreasing conversion efficiency.

In the case of a heterojunction such as Si/SiGe, an interface functions to trap or remove carriers generated by defects. Therefore, when a SiGe thin film solar cell is manufactured in an n-Si/Si-graded i-SiGe/p-SiGe (or p-Si/Si-graded i-SiGe/n-SiGe) structure instead of manufactured in a conventional n-Si/i-SiGe/p-Si structure, the SiGe thin film solar cell is manufactured as a homojunction, not as a heterojunction, thus the n-Si/Si-graded i-SiGe/p-SiGe structure is advantageous. Also, when the SiGe thin film solar cell is manufactured in an i-SiGe/n-Si or i-SiGe/p-Si structure, an i-n or i-p interface is formed, thereby exhibiting a bandgap-narrowing phenomenon. Thus, the bandgap-narrowing phenomenon in heterojunction has a negative influence on the efficiency of the SiGe thin film solar cell. However, when the SiGe thin film solar cell is manufactured only as a homojunction, such a negative influence is removed, and thus, the efficiency of the SiGe thin film solar cell is increased.

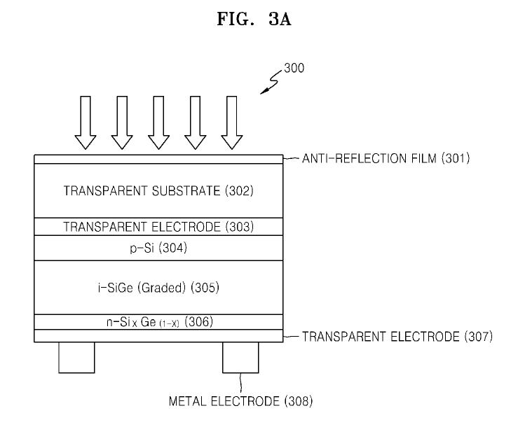

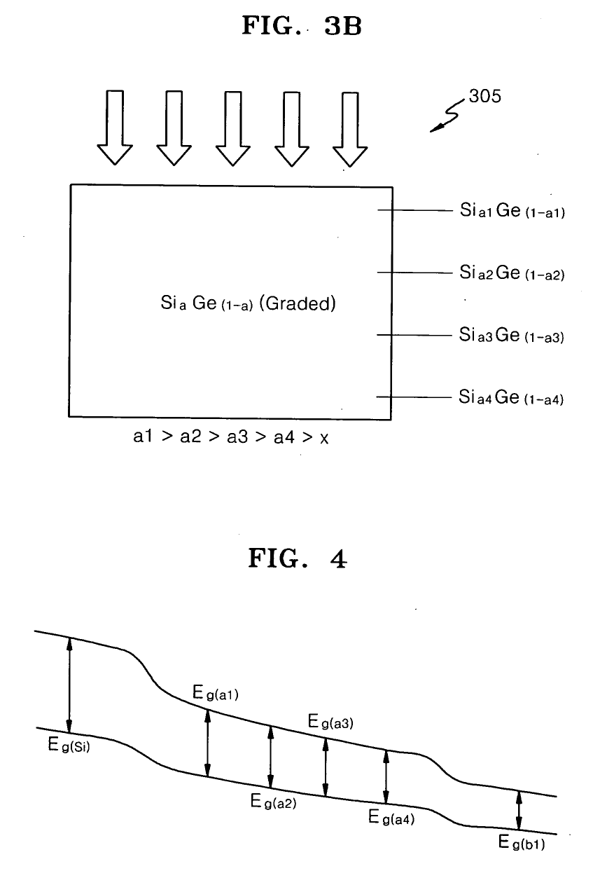

FIG. 3A shows a SiGe thin film solar cell 300 according to an embodiment of the present invention, and FIG. 3B shows a light absorbing layer of the SiGe thin film solar cell 300 of FIG. 3A in more detail.

The SiGe thin film solar cell 300 according to the current embodiment includes an anti-reflection film 301, a transparent substrate 302, transparent electrodes 303 and 307, a p-type Si semiconductor layer 304, an i-type SiGe semiconductor layer 305, an n-type SiGe semiconductor layer 306, and metal electrodes 308. In FIG.3A, a single metal electrode layer can be used instead of transparent electrode 307 and metal electrode 308.

A light-absorbing layer of the SiGe thin film solar cell 300 includes the p-type Si semiconductor layer 304, the i-SiGe semiconductor layer 305, and the n-type SiGe semiconductor layer 306. Normally, p-type layer and n-type layer are required to form p-i-n diode device and behave as conducting layers carrying holes or electrons, respectively. Among the p-, i-, and n-layers, the major light absorbing layer is i-SiGe layer. In the light-absorbing layer, a Ge composition ratio of the SiGe layer disposed in the closest portion from an incident direction of solar light is lowest (Siₐ₁Ge₍₁₋ₐ₁₎), and a Ge composition ratio of the SiGe layer disposed in the farthest portion is highest (Siₐ₄Ge₍₁₋ₐ₄₎). The a1 is 1, and thus the (Siₐ₁Ge₍₁₋ₐ₁₎) region may be a Si region. Thus, the light-absorbing layer should be manufactured so that the Si composition ratio in SiGe layer varies in the order of a1>a2>a3>a4. Here, the a1, a2, a3, and a4 denote the average composition ratio (Si composition in SiGe layer) of their corresponding layer, and it does not mean that their corresponding layer includes four layers.

That is, the Ge composition ratio increases as the distance between the transparent substrate 302 and the SiGe layer (that is, the distance between the transparent substrate 302 and the portion to which solar light is incident) increases.

According to the current embodiment, a bandgap of a portion having the smallest amount of Ge is largest, and as the amount of Ge increases, the bandgap is reduced. In such a structure, since a heterojunction does not exist, unlike the case where a plurality of thin films each having a different amount of Ge are manufactured as a multi-layer, a possibility to trap and remove carriers can be significantly decreased. The SiGe layer having such gradual and successive composition gradient may be used in a solar cell having a multi-junction structure such as a double junction structure, a triple junction structure, etc., as well as a single junction structure shown FIG. 3A.

Here, the multi-junction structure is a structure formed by repetitively arranging a p-i-n unit structure including a p-type semiconductor layer, an n-type semiconductor layer, an intrinsic(i-) semiconductor layer which is interposed between the p-type semiconductor layer and the n-type semiconductor layer.

FIG. 4 shows a bandgap of the SiGe thin film solar cell 300 of FIG. 3A.

Referring to FIG. 4, the size of bandgap gradually decreases in the order of E_{g(Si)}>E_{g(a1)}>Eg₍ₐ₂₎>Eg₍ₐ₃₎>Eg₍ₐ₄₎>Eg_{(b1)}. For example, the composition of very first position of i-layer interfaced with p-Si is Si 100% and the Ge composition of the last position of i-layer interfaced with n-SiGe layer is the same as n-SiGe layer.

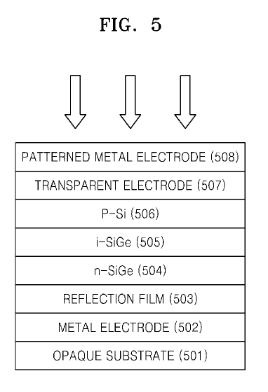

FIG. 5 shows a solar cell using an opaque substrate 501, according to another embodiment of the present invention.

Referring to FIG. 5, the solar cell according to the current embodiment has a reverse structure to the structure of the solar cell described in FIG. 3A. That is, the solar cell has a structure where a metal electrode 502, a reflection film 503, an n-type SiGe semiconductor layer 504, an i-SiGe semiconductor layer 505, a p-type Si semiconductor layer 506, a transparent electrode 507, and a patterned-metal electrode 508 are sequentially formed on the opaque substrate 501.

According to another embodiment, the p-type Si semiconductor layer 506 may be replaced with a p-type SiGe semiconductor layer having a Ge composition ratio lower than that of the i-SiGe semiconductor layer 505. Also, the i-SiGe semiconductor layer 505 may be formed so that the composition varies gradually as shown in FIG. 3B.

Similarly to the structure of the SiGe thin film solar cell 300 of FIG. 3A, a light-absorbing layer is manufactured so that a Ge composition ratio of a SiGe layer disposed in the closest portion from an incident direction of solar light is lowest and a Ge composition ratio of a SiGe layer disposed in the farthest portion from an incident direction of solar light is highest. Accordingly, the n-type SiGe semiconductor layer 504 has a Ge composition ratio higher than that of the i-SiGe semiconductor layer 505.

That is, the SiGe thin film solar cell 300 of FIG. 3A is manufactured so that as the distance between the transparent substrate 302 and the SiGe layer increases, the Ge composition ratio increases. On the other hand, in the current embodiment shown in FIG. 5, since the position of the opaque substrate 501 is opposite with respect to the incident direction of solar light, as the distance between the opaque substrate 501 and the SiGe layer increases, the Ge composition ratio decreases.

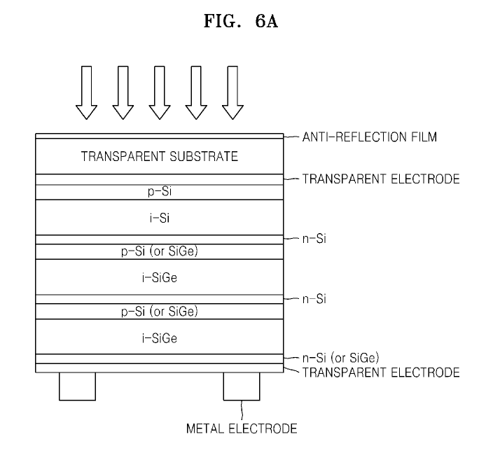

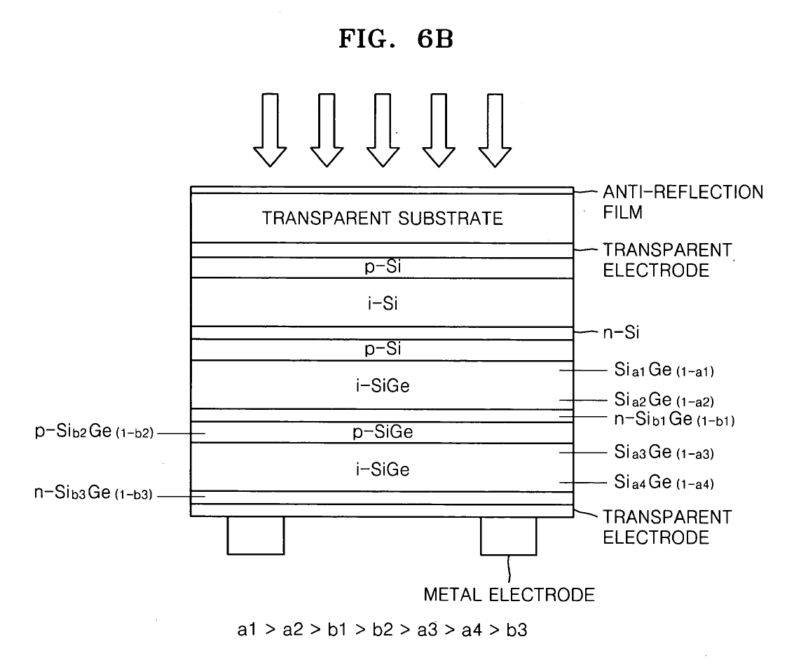

FIG. 6A shows a conventional SiGe thin film solar cell having a triple junction structure. FIG. 6B shows a SiGe thin film solar cell having a triple junction structure, according to an embodiment of the present invention.

That is, FIG. 6B shows a structure in which a SiGe layer, having a composition gradient of which a Ge composition ratio is gradually increased, is applied to the conventional SiGe thin film solar cell having a triple junction structure of FIG. 6A.

Referring to FIG. 6B, the composition of each of the thin films forming a light-absorbing layer of the SiGe thin film solar cell may be gradually varied from Si to SiGe. Here, p-type (p-), intrinsic (i-), n-type (n-) thin films may be formed of SiGe thin films having different Ge compositions, respectively. In this case, the SiGe thin film including the smallest amount of Ge may be disposed in the closest portion from an incident direction of solar light, and the SiGe thin film including the largest amount of Ge may be disposed in the farthest portion from an incident direction of solar light.

In the SiGe thin film solar cell having a multi-junction structure of FIG. 6B, the SiGe thin film having the smallest amount of Ge may be disposed in a close part from an incident direction of solar light, and the SiGe thin film having the largest amount of Ge may be disposed in a far portion from an incident direction of solar light.

For example, as shown in FIG. 6B, if the SiGe thin film solar cell is manufactured to have a composition gradient of Ge from a i-SiGe layer, a1 is 1. That is, the layer corresponding to is formed as only a Si film at first and then Ge is added to the layer corresponding to. The SiGe thin film solar cell may be manufactured so as to satisfy the condition of a1>a2, then an n-SiGe layer may have a composition gradient of Ge or may be manufactured as a SiGe layer having a single composition. At least, the condition of a2>b1 should be satisfied, and a p-Si_{b2}Ge_{(1-b2)} layer to be manufactured next may be manufactured as a layer having a single composition similar to the n-Si_{b1}Ge_{(1-b1)} layer or as a layer having more composition of Ge and having a successive gradient of Ge, and the condition of b1≧b2 should be satisfied. Next, the i-SiGe layer may be manufactured to satisfy the condition of a3>a4, and then the n-Si_{b3}Ge_{(1-b3)} layer may be manufactured as a SiGe layer having a single composition or having a composition gradient of Ge, and the condition of b1≧b2≧b3 should be satisfied.

The SiGe thin film solar cell of the current embodiment may be modified in various ways as follows. The SiGe thin film solar cell may include only one thin film having a successive composition gradient of Ge, for example, p-Si/i-Si/n-Si//p-Si/i-Si/n-Si//p-Si/i-SiGe(graded)/n-SiGe, or may include a plurality of layers.

The SiGe thin film having such a composition gradient may be deposited by chemical vapor deposition, atmospheric pressure/reduced pressure chemical vapor deposition, plasma chemical vapor deposition, or the like. Besides, several different kinds of thin film deposition methods may be used to deposit a thin film having a composition gradient.

In the current embodiment, a substrate may be a metal plate, a metal foil, a polymer substrate, a ceramic substrate, or the like, as well as glass.

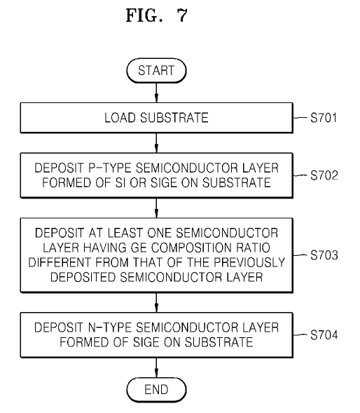

FIG. 7 is a flowchart of a method of manufacturing a SiGe thin film solar cell, according to an embodiment of the present invention. Normally the processes S702, S703, and S704 are carried out in-situ in one chamber or three chambers in a deposition system without exposing the substrate to air.

Referring to FIG. 7, a substrate including an electrode is loaded (S701), then a p-type semiconductor layer formed of Si or SiGe is deposited on the substrate (S702).

At least one semiconductor layer having a Ge composition ratio different from that of the previously deposited semiconductor layer is deposited (S703) to form a light-absorbing layer. Here, a light-absorbing layer may include the semiconductor layer deposited on the substrate and the at least one semiconductor layer which is deposited on the substrate.

Then, n-type semiconductor layer formed of SiGe is deposited on the substrate (S704).

According to the current embodiment, when the substrate is a transparent substrate that transmits light of a visible light region, at least one semiconductor layer having a Ge composition ratio higher than that of the previously deposited semiconductor layer may be sequentially deposited.

According to the current embodiment, when the substrate is an opaque substrate that does not transmit a visible light, at least one semiconductor layer having a Ge composition ratio lower than that of the previously deposited semiconductor layer may be sequentially deposited.

The SiGe thin film according to the current embodiment is manufactured to have a characteristic in which a Ge composition ratio varies continuously to correspond to a composition gradient according to the distance between the substrate and the portion to which solar light is incident.

For example, the SiGe thin film may be manufactured so that the Ge composition ratio of the SiGe thin film gradually increases or decreases by gradually varying relative composition ratios of SiH₄, which is a Si precursor, and GeH₄, which is a Ge precursor, among a reacting gas.

The above method is just an example, and the SiGe thin film may be manufactured by other methods. For example, when the SiGe thin film having a composition gradient is deposited then a new SiGe thin film is deposited, the relative composition ratios of the SiH₄ and GeH₄ may be maintained equally with that of the SiGe thin film, which is previously deposited, in order to allow the new SiGe thin film to have a constant SiGe composition. Alternatively, the relative composition ratios of the SiH₄ and GeH₄ may be deposited to have a different composition from the SiGe thin film, which is previously deposited, in order to allow the new SiGe thin film to have a composition gradient.

Here, the SiH₄ and GeH₄ are just examples of a Si precursor and a Ge precursor, respectively, and thus different kinds of Si and Ge precursors may also be used.

The sequential deposition method according to the current embodiment may be a digital chemical vapor deposition method, an atmospheric pressure chemical vapor deposition method, a reduced pressure chemical vapor deposition method, a plasma enhanced chemical vapor deposition method, a different type of reactive thin film deposition method, or the like.

As such, in the SiGe thin film solar cell, crystal defects and stress may be minimized by performing a method of gradually reducing the amount of Ge of the light-absorbing layer, that is, using a structure having a gradual composition gradient. When a SiGe layer is manufactured to have a gradual composition gradient, stress that may occur by sudden changes of a Ge composition can be reduced, thereby minimizing defects. Also, as the Ge composition increases, the depth of light absorption decreases, thereby performing a more efficient light absorption. In order to increase light conversion efficiency, a thin film having a large bandgap may be disposed in a close portion from an incident direction of light, and a thin film having a small bandgap may be disposed in an opposite direction to the incident direction of light.

In such a structure, since an interface does not exist unlike the case where a plurality of thin films each having a different amount of Ge are manufactured as a multi-layer, a possibility to trap and remove carriers can be significantly decreased. The SiGe layer having a gradual composition gradient may be used in a multi-junction solar cell such as a double junction solar cell, a triple junction solar cell, or the like, as well as in a single junction solar cell.

A light absorbing layer according to current embodiment may be formed to have a continuous composition gradient. Also, for convenience of manufacture, the light absorbing layer may be formed by continuously depositing a plurality of layers having discontinuous intervals of Ge composition ratios. In this case, an interface still can be fabricated not to be abrupt, thus consequently, the same effect as the light absorbing layer which is formed to have a continuous composition gradient can be obtained.

According to the present invention, crystal defects and stress can be minimized by gradually controlling a Ge composition ratio of a light-absorbing layer of a solar cell, and a more effective use of absorbed light can be realized.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A solar cell comprising:
a substrate having an electrode layer; and
a light-absorbing layer formed on the substrate and comprising a plurality of semiconductor layers which comprise Si or SiGe and have different Ge composition ratios, wherein the Ge composition ratio of the light-absorbing layer varies so as to correspond to a Ge composition gradient according to the distance between the light-absorbing layer and the substrate.

2. The solar cell of claim 1, wherein at least one of the semiconductor layers has a Ge composition ratio of 0.

3. The solar cell of claim 1, wherein when the substrate is a transparent substrate that transmits light of a visible light region, the Ge composition ratio of the semiconductor layers of the light-absorbing layer increases as the distance between the semiconductor layer and the substrate increases.

4. The solar cell of claim 3, wherein the light-absorbing layer comprises a p-type semiconductor layer adjacent to the substrate; an i-semiconductor layer formed on the p-type semiconductor layer and having a Ge composition ratio higher than that of the p-type semiconductor layer; and an n-type semiconductor layer formed on the i-type semiconductor layer and having a Ge composition ratio higher than that of the i-type semiconductor layer.

5. The solar cell of claim 4, wherein the i-semiconductor layer comprises a plurality of SiGe layers having Ge composition ratios which increase as the distance between the i-semiconductor layer and the p-type semiconductor layer increases.

6. The solar cell of claim 1, wherein when the substrate is an opaque substrate that does not transmit light of a visible rays region, the Ge composition ratio of the semiconductor layers of the light-absorbing layer decreases as the distance between the semiconductor layer and the substrate increases.

7. The solar cell of claim 6, wherein the semiconductor layers comprise an n-type semiconductor layer adjacent to the substrate; an i-semiconductor layer which is formed over the n-type semiconductor layer and has a Ge composition ratio lower than that of the n-type semiconductor layer; and a p-type semiconductor layer which is formed over the i-type semiconductor layer and has a Ge composition ratio lower than that of the i-type semiconductor layer.

8. The solar cell of claim 1, wherein the semiconducting layers comprise at least one p-i-n unit structure comprising a p-type semiconductor layer, an n-type semiconductor layer, and an i-semiconductor layer formed between the p-type semiconductor layer and the n-type semiconductor layer, and the i-semiconductor layer has a Ge composition ratio higher than that of the p-type semiconductor layer comprised in the same p-i-n unit structure and lower than that of the n-type semiconductor layer comprised in the same p-i-n unit structure.

9. The solar cell of claim 8, wherein when the p-i-n unit structure comprises a first unit structure adjacent to the substrate and a second unit structure formed under the first unit structure, and when the substrate is a transparent substrate transmitting light of a visible region, a Ge composition ratio of the i-semiconductor layer of the second unit structure is higher than that of the i-semiconductor layer of the first unit structure.

10. A method of manufacturing a solar cell, comprising:
loading a substrate having an electrode layer;
depositing a semiconductor layer comprising Si or SiGe on the substrate; and
forming an i-semiconductor layer by depositing at least one semiconductor layer having a Ge composition ratio different from that of the previously deposited semiconductor layer, wherein the Ge composition ratio of the i-semiconductor layer varies so as to correspond to a constant composition gradient according to the distance between the i-semiconductor layer being deposited and the substrate.

11. The method of claim 10, wherein when the substrate is a transparent substrate transmitting light of a visible region, the forming of the light-absorbing layer comprises sequentially depositing at least one semiconductor layer having a Ge composition ratio higher than that of the previously deposited semiconductor layer.

12. The method of claim 10, wherein when the substrate is an opaque substrate that does not transmit light of a visible region, the forming of the light-absorbing layer comprises depositing at least one semiconductor layer having a Ge composition ratio lower than that of the previously deposited semiconductor layer.

13. The method of claim 10, wherein the forming of the light-absorbing layer comprises depositing by using at least one of a digital chemical vapor deposition method, an atmospheric pressure chemical vapor deposition method, a reduced pressure chemical vapor deposition method, a plasma enhanced chemical vapor deposition method, and a reactive thin film deposition method.
